(19) United States
(12) Patent Application Publication
(10) Pub. No.: US 2023/0006625 A1
(43) Pub. Date: Jan. 5, 2023

(54) Distributed Circuit

(71) Applicant: Nippon Telegraph and Telephone Corporation, Tokyo (JP)

(72) Inventors: Teruo Jo, Tokyo (JP); Munehiko Nagatani, Tokyo (JP); Hideyuki Nosaka, Tokyo (JP)

(21) Appl. No.: 17/778,752

(22) PCT Filed: Dec. 9, 2019
(86) PCT No.: PCT/JP2019/048046

§ 371 Date: May 20, 2022

(51) Int. Cl. H03F 3/60; H03D 7/12; H01P 3/08

(52) U.S. Cl. CPC H03F 3/607; H03D 7/12; H01P 3/08

(57) ABSTRACT

A distributed amplifier includes a transmission line configured so as to transmit a signal, a variable capacitor having one end connected to the transmission line and the other end connected to the ground, and configured so that the capacitance is adjustable, and a variable capacitor having one end connected to the transmission line and the other end connected to the ground, and configured so that the capacitance is adjustable. The transmission line is configured in such a manner that the inductance is adjustable.

### CROSS-REFERENCE TO RELATED APPLICATIONS

This application is a national phase entry of PCT Application No. PCT/JP2019/048046, filed on Dec. 9, 2019, which application is hereby incorporated herein by reference.

### TECHNICAL FIELD

The present invention relates to a distributed circuit such as a distributed amplifier or a distributed mixer.

### BACKGROUND ART

Broadband amplifier integrated circuits (ICs) are desired in various systems of high-speed optical communications, wireless communications, high-resolution radars, and the like. Distributed amplifiers are conventionally proposed since these amplifiers are technically feasible to widen the bandwidth thereof (see Non-Patent Literature 1). In the distributed amplifiers, the parasitic capacitances of transistors are incorporated into input/output transmission lines, to achieve impedance matching. Further, in the distributed amplifiers, matching phase velocities between the input transmission line and the output transmission line can realize broadband signal amplification.

The impedances of ordinary high-frequency radio frequency (RF) circuits or devices are often designed to be 50Ω. When the connection with these circuits or devices is taken into consideration, it is necessary to make input/output impedances of the amplifier match with 50Ω. Impedance Zo of a lossless transmission line can be represented by Zo=<(L/C) in which L represents the inductance and C represents the capacitance component, per unit length of this transmission line. In the distributed amplifier, in a state where parasitic capacitance Cpara of the transistor is added to capacitance component C of the transmission line, the impedance (√L/(C+Cpara)) is designed to be 50Ω. The transmission line including the parasitic capacitance of the transistor is hereinafter referred to as “artificial transmission line”.

Meanwhile, phase velocity v of the transmission line is represented by v=1/√(LC). In the distributed amplifier, broadband amplification can be realized by designing the phase velocities of the input/output artificial transmission lines to be the same, in a state where the impedance of each of the input/output artificial transmission lines is matched with 50Ω.

However, actually manufactured artificial transmission lines are affected by manufacturing errors and therefore the input/output impedances and the phase velocities often deviate from designed values. The deviations in impedance and phase velocity from the designed values lead to deterioration of the distributed amplifier in reflection characteristics or band deterioration. Therefore, a circuit that adjusts the impedance and the phase velocity after manufacturing is required.

Conventionally, as a phase velocity adjusting circuit, a circuit in which variable capacitors are added to the transmission line so as to adjust the capacitance, as illustrated in FIG. 17, is proposed (see Non-Patent Literature 2). A distributed amplifier illustrated in FIG. 17 includes an input-side transmission line CPW10a whose input end is connected to a signal input terminal 1, an output-side transmission line CPW20a whose terminating end is connected to a signal output terminal 2, an input terminating resistor R1 connecting a terminating end of the transmission line CPW10a to the ground, an output terminating resistor R2 connecting an input end of the transmission line CPW20a to the ground, a plurality of unit cells 3 arranged along the transmission lines CPW10a and CPW20a, each unit cell having an input terminal connected to the transmission line CPW10a and an output terminal connected to the transmission line CPW20a, a plurality of variable capacitors Ctune1 provided between the transmission line CPW10a and the ground, and a plurality of variable capacitors Ctune2 provided between the transmission line CPW20a and the ground. The transmission line CPW10a is configured to include a plurality of transmission lines CPW1 connected in series. Similarly, the transmission line CPW20a is configured to include a plurality of transmission lines CPW2 connected in series.

FIG. 18 is an equivalent circuit diagram of the distributed amplifier illustrated in FIG. 17. In FIG. 18, L1 and L2 are inductors and C1 and C2 are capacitors.

In the distributed amplifier illustrated in FIG. 17, since only the capacitance is adjusted by the variable capacitors Ctune1 and the variable capacitors Ctune2, there is a problem that the phase velocity and the impedance cannot be adjusted independently.

For example, if the capacitances of the variable capacitors Ctune1 and Ctune2 are increased to slow down the phase velocity, the impedances of the transmission lines CPW10a and CPW20a decrease and deviate from 50Ω. As a result, the reflection characteristics of the distributed amplifier will deteriorate.

As described above, in the conventional technique, it was difficult to realize a distributed amplifier that can adjust the input/output impedances and the phase velocities, after manufacturing, without deteriorating both of the reflection characteristics and band characteristics. It should be noted that this problem occurs similarly not only in the distributed amplifier but also in other distributed circuits.

### CITATION LIST

### Non-Patent Literature

Non-Patent Literature 1: Stavros Giannakopoulos, et al., “Ultra-broadband common collector-cascode 4-cell distributed amplifier in 250 nm InP HBT technology with over 200 GHz bandwidth”, 2017 12th European Microwave Integrated Circuits Conference (EuMIC), IEEE, 2017. Non-Patent Literature 2: Amit S. Nagra, and Robert A. York, “Distributed analog phase shifters with low insertion loss”, IEEE Transactions on Microwave Theory and Techniques, Vol. 47, No. 9, pp. 1705-1711, 1999.

### SUMMARY

### Technical Problem

In order to solve the above-described problems, embodiments of the present invention intends to provide a distributed circuit capable of adjusting the input/output impedances and the phase velocities without deteriorating both of reflection characteristics and band characteristics.

### Means for Solving the Problem

A distributed circuit of embodiments of the present invention includes a transmission line configured so as to transmit a signal, and a variable capacitor having one end connected to the transmission line and the other end connected to the ground, and is configured so that the capacitance is adjustable, wherein the transmission line is configured in such a manner that the inductance is adjustable.

### Effects of Embodiments of the Invention

According to embodiments of the present invention, providing the variable capacitor and configuring the transmission line so that the inductance is adjustable can independently adjust the input/output impedances and the phase velocities, and can realize a distributed circuit in which the input/output impedances and the phase velocities are adjustable after manufacturing, without deteriorating both the reflection characteristics and the band characteristics.

### BRIEF DESCRIPTION OF THE DRAWINGS

FIG. 1 is a circuit diagram illustrating a configuration of a distributed amplifier according to a first embodiment of the present invention.

FIG. 2 is a circuit diagram illustrating a configuration of a unit cell of the distributed amplifier according to the first embodiment of the present invention.

FIG. 3 is an equivalent circuit diagram illustrating the distributed amplifier according to the first embodiment of the present invention.

FIG. 4A is a diagram illustrating simulation results with respect to input/output impedances of the distributed amplifier according to the first embodiment of the present invention.

FIG. 4B is a diagram illustrating simulation results with respect to input/output impedances of a conventional distributed amplifier.

FIG. 5A is a diagram illustrating simulation results with respect to input/output phase characteristics of the distributed amplifier according to the first embodiment of the present invention.

5B is a diagram illustrating simulation results with respect to input/output phase characteristics of a conventional distributed amplifier.

FIG. 6 is a diagram illustrating simulation results with respect to S-parameters in the distributed amplifier according to the first embodiment of the present invention as well as in a conventional distributed amplifier.

FIG. 7 is a perspective diagram illustrating a configuration of a transmission line according to a second embodiment of the present invention.

FIG. 8 is a diagram illustrating simulation results with respect to equivalent inductance of the transmission line when the magnitude of a variable resistor is changed in the second embodiment of the present invention.

FIG. 9 is a diagram illustrating simulation results with respect to equivalent capacitance of transmission line when the magnitude of a variable resistor is changed in the second embodiment of the present invention.

FIG. 10 is a perspective diagram illustrating another configuration of the transmission line according to the second embodiment of the present invention.

FIG. 11 is a perspective diagram illustrating another configuration of the transmission line according to the second embodiment of the present invention.

FIG. 12 is a perspective diagram illustrating a configuration of a transmission line according to a third embodiment of the present invention.

FIG. 13 is a perspective diagram illustrating a configuration of a transmission line according to a fourth embodiment of the present invention.

FIG. 14 is a perspective diagram illustrating another configuration of the transmission line according to the fourth embodiment of the present invention.

FIG. 15 is a circuit diagram illustrating a configuration of a distributed mixer according to a fifth embodiment of the present invention.

FIG. 16 is a circuit diagram illustrating a unit cell configuration of the distributed mixer according to the fifth embodiment of the present invention.

FIG. 17 is a circuit diagram illustrating a configuration of a conventional distributed amplifier.

FIG. 18 is an equivalent circuit diagram of the distributed amplifier of FIG. 17.

### DETAILED DESCRIPTION OF ILLUSTRATIVE EMBODIMENTS

### First Embodiment

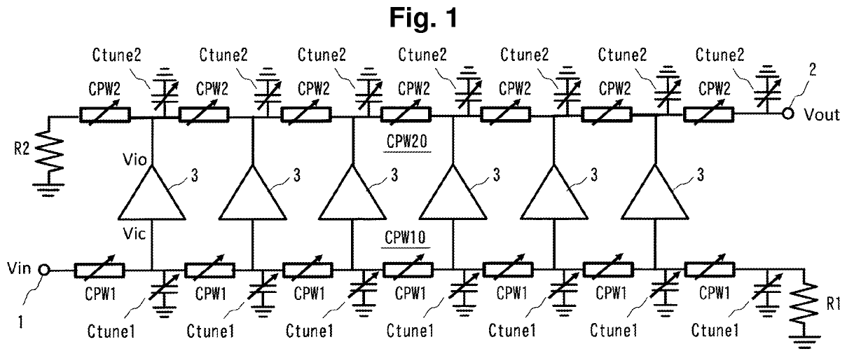

Hereinafter, embodiments of the present invention will be described with reference to attached drawings. FIG. 1 is a circuit diagram illustrating a configuration of a distributed amplifier according to a first embodiment of the present invention. The distributed amplifier of the present embodiment includes an input-side transmission line CPW10 whose input end is connected to a signal input terminal 1, an output-side transmission line CPW20 whose terminating end is connected to a signal output terminal 2, an input terminating resistor R1 connecting a terminating end of the transmission line CPW10 to the ground, an output terminating resistor R2 connecting an input end of the transmission line CPW20 to the ground, a plurality of unit cells 3 arranged along the transmission lines CPW10 and CPW20, each unit cell having an input terminal connected to the transmission line CPW10 and an output terminal connected to the transmission line CPW20, a plurality of variable capacitors Ctune1 provided between the transmission line CPW10 and the ground, and a plurality of variable capacitors Ctune2 provided between the transmission line CPW20 and the ground.

The transmission line CPW10 is configured to include a plurality of transmission lines CPW1 connected in series. Similarly, the transmission line CPW20 is configured to include a plurality of transmission lines CPW2 connected in series.

In FIG. 1, Vin represents an input signal of the distributed amplifier, Vout represents an output signal of the distributed amplifier, Vic represents an input signal of the unit cell 3, and Vio is an output signal of the unit cell 3.

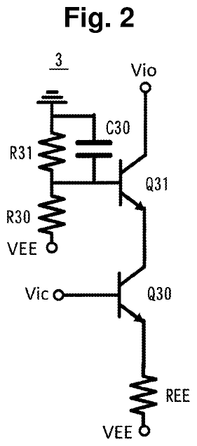

As illustrated in FIG. 2, each unit cell 3 includes an input transistor Q30 whose base terminal is connected to the transmission line CPW1, an output transistor Q31 having a collector terminal connected to the transmission line CPW2 and an emitter terminal connected to a collector terminal of the input transistor Q30, an emitter resistor REE having one end connected to an emitter terminal of the input transistor Q30 and the other end connected to a power source voltage VEE, a resistor R30 having one end connected to the power source voltage VEE and the other end connected to a base terminal of an output transistor Q2, a resistor R31 having one end connected to the base terminal of the output transistor Q2 and the other end connected to the ground, and a capacitor C30 having one end connected to the base terminal of the output transistor Q2 and the other end connected to the ground.

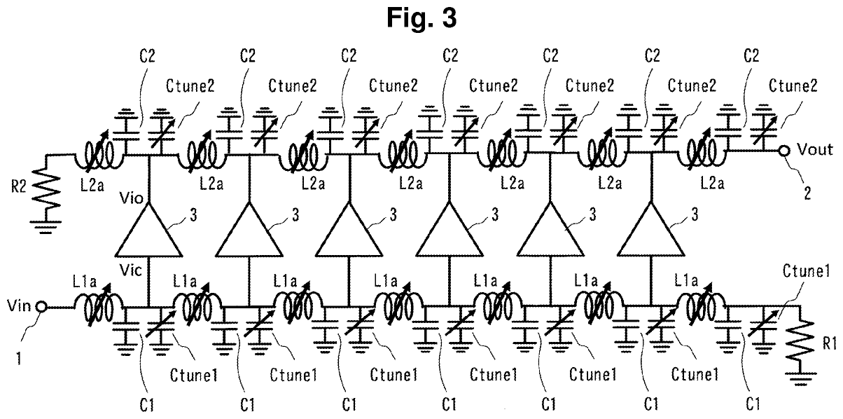

FIG. 3 is an equivalent circuit diagram of the distributed amplifier of the present embodiment. In FIG. 3, Lia and L2a are variable inductors and C1 and C2 are capacitors.

In the present embodiment, introducing a circuit that adjusts both inductance and capacitance into the distributed amplifier can independently adjust the input/output impedances and the phase velocities of the distributed amplifier.

Specifically, the transmission lines CPW1 and CPW2 are configured in such a manner that their inductances can be adjusted. That is, in the transmission line CPW1, the inductance is independently adjustable in a region between the signal input terminal 1 and a first-stage unit cell 3 (the leftmost unit cell 3 in FIG. 1), a region between the unit cells, and a region between the final-stage unit cell 3 (the rightmost unit cell 3 in FIG. 1) and the input terminating resistor R1. In transmission line CPW2, the inductance is adjustable independently in a region between the output terminating resistor R2 and the first-stage unit cell 3, a region between the unit cells, and a region between the final-stage unit cell 3 and the signal output terminal 2. Detailed configurations of the transmission lines CPW1 and CPW2 will be described below.

The variable capacitor Ctune1 is provided at a position between the transmission lines CPW1, and is also provided at a position between the transmission line CPW1 and the input terminating resistor R1. The variable capacitor Ctune2 is provided at a position between the transmission lines CPW2, and is also provided at a position between the transmission line CPW2 and the signal output terminal 2. The variable capacitors Ctune1 and Ctune2 are, for example, varactors.

In the present embodiment, since the input/output impedances and the phase velocities can be adjusted independently, it is possible to realize a distributed amplifier in which the input/output impedances and the phase velocities are adjustable after manufacturing, without deteriorating both the reflection characteristics and the band characteristics.

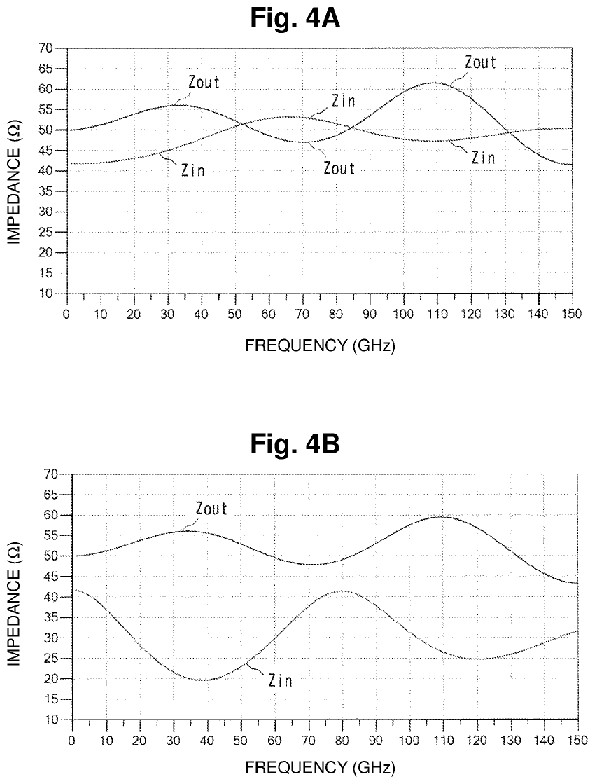

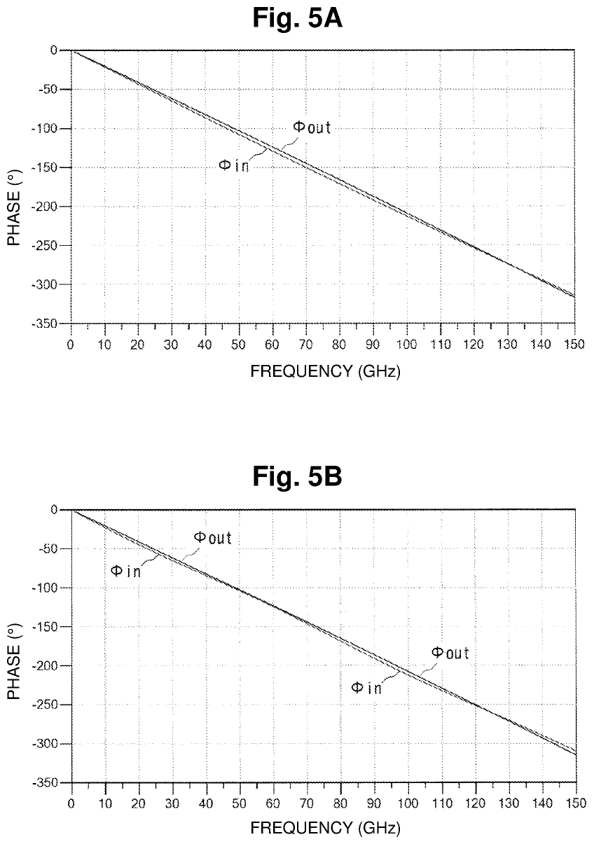

FIGS. 4A and 5A illustrate simulation results, in the distributed amplifier of the present embodiment, when the phase velocities of the transmission line CPW10 and the transmission line CPW20 are matched by adjusting both of the inductance and the capacitance of the input-side transmission line CPW10 with the variable inductor (the transmission line CPW1) and the variable capacitor Ctune1. FIG. 4A illustrates input/output impedances of the distributed amplifier of the present embodiment. Zin represents the input impedance, and Zout represents the output impedance. FIG. 5A illustrates input/output phase characteristics of the distributed amplifier of the present embodiment. Tin represents the input phase, and pout represents the output phase.

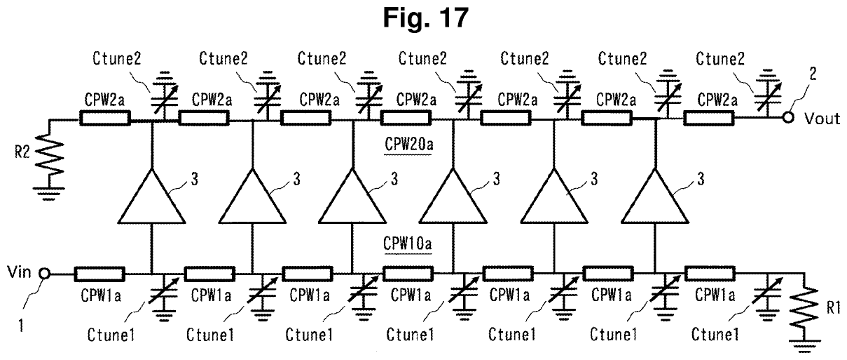

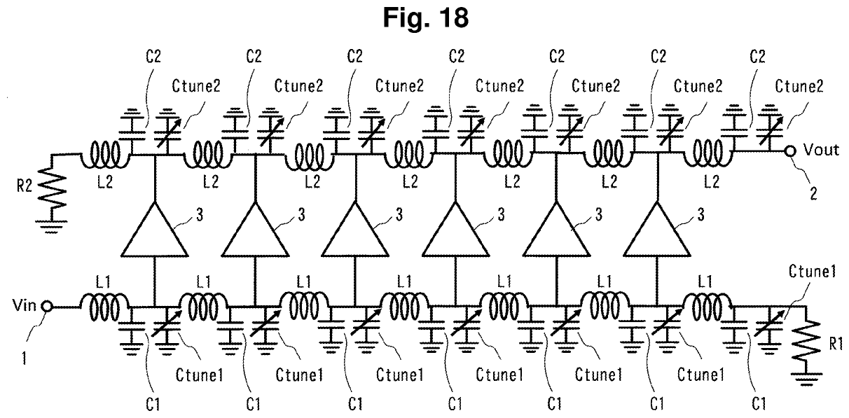

Further, FIGS. 4B and 5B illustrate simulation results, in the conventional distributed amplifier illustrated in FIG. 17, when only the capacitance of the input-side transmission line CPW10 is adjusted by the variable capacitor Ctune1 and the phase velocities of the transmission line CPW10 and the transmission line CPW20 are matched. FIG. 4B illustrates input/output impedances of the conventional distributed amplifier. FIG. 5A illustrates input/output phase characteristics of the conventional distributed amplifier.

It is understood from FIG. 5A that the phase velocities of the transmission line CPW10 and the transmission line CPW20 are the same in the distributed amplifier of the present embodiment. Similarly, it is understood from FIG. 5B that the phase velocities of the transmission line CPW10 and the transmission line CPW20 are the same in the conventional distributed amplifier.

On the other hand, it is understood from FIG. 4B that the input impedance Zin of the conventional distributed amplifier deviates from 50Ω, but as illustrated in FIG. 4A the input impedance Zi of the distributed amplifier of the present embodiment can be adjusted to approximately 50Ω.

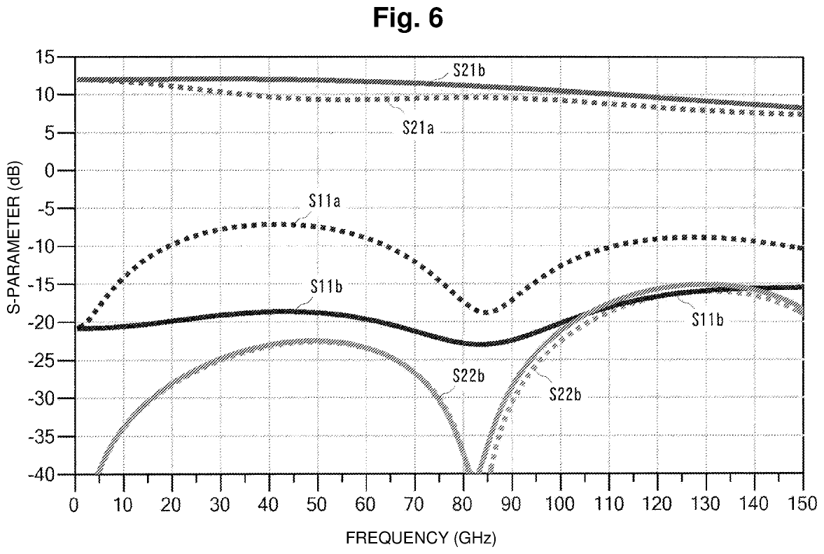

Further, FIG. 6 illustrates simulation results with respect to S-parameters in the distributed amplifier of the present embodiment as well as in the conventional distributed amplifier. In FIG. 6, S11a represents S-parameter S11 of the conventional distributed amplifier, S11b represents S-parameter S11 of the distributed amplifier of the present embodiment, S21a represents S-parameter S21 of the conventional distributed amplifier, S21b represents S-parameter S21 of the distributed amplifier of the present embodiment, S22a represents S-parameter S22 of the conventional distributed amplifier, and S22b represents S-parameter S22 of the distributed amplifier of the present embodiment.

It is understood from FIG. 6 that using the configuration of the present embodiment can improve pass characteristics (S21) and input reflection characteristics (S11) while realizing output reflection characteristics (S22) equivalent to the conventional characteristics.

### Second Embodiment

Next, a second embodiment of the present invention will be described. As described in the first embodiment, the transmission line of the present invention is provided with an inductance adjustment function. Several circuits capable of changing the inductance have been proposed in the past (Literature “Ehsan Adabi, and Ali M. Niknejad, “Broadband variable passive delay elements based on an inductance multiplication technique”, 2008 IEEE Radio Frequency Integrated Circuits Symposium, IEEE, 2008”). However, combining the proposed circuits with distributed amplifiers was difficult.

For example, as a variable inductor circuit, a configuration for switching a plurality of inductors has been proposed. However, this configuration requires insertion of switch in series with the signal. The switch is usually configured by a transistor, but a parasitic resistance and a parasitic capacitance of the transistor cause gain reduction and band deterioration. Therefore, the variable inductor circuit configured to switch a plurality of inductors by a switch cannot be used for broadband amplifiers.

Further, as a variable inductor circuit, a configuration using mutual inductance has been proposed. However, in the above-described configuration, it is necessary to distribute input signal and generate mutual induction between two distributed signal lines. Therefore, the electric power to be input to the amplifier decreases due to power distribution and the gain decreases. In addition, a broadband matching circuit is required for a power distributor. Thus, the variable inductor circuit configured to use mutual inductance cannot be used for broadband amplifiers.

In the present embodiment, a configuration in which a variable resistor is inserted between a ground plate configuring the transmission line and the ground and the variable resistor value is adjusted to make the inductance of the transmission line variable.

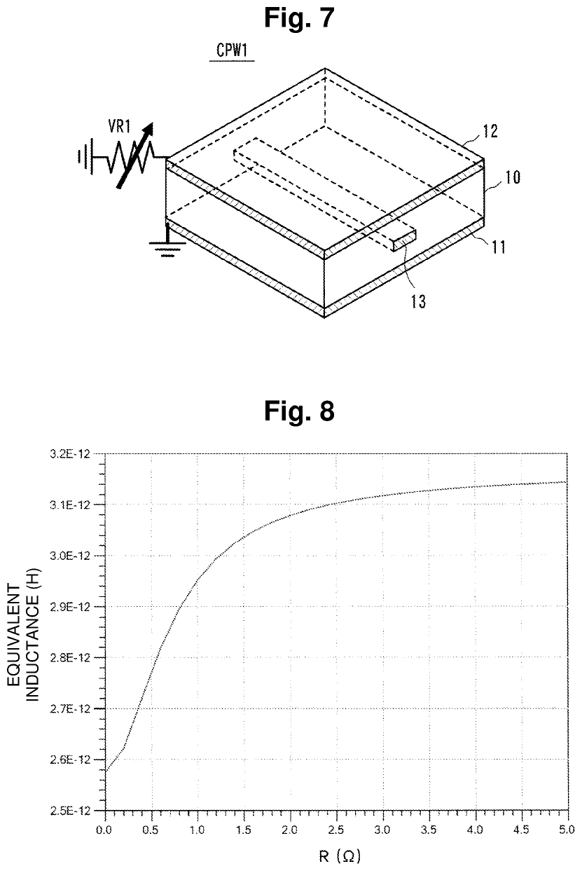

FIG. 7 is a perspective diagram illustrating a configuration of the transmission line CPW1 of the present embodiment. The transmission line CPW1 of the present embodiment includes a rectangular planar dielectric 10, a ground plate 11 composed of a planar conductor formed on a back surface of the dielectric 10 and connected to the ground, a ground plate 12 composed of a planar conductor formed on a front surface of the dielectric 10, a signal line 13 composed of a belt-shaped conductor formed in the dielectric 10 so as to be parallel to the ground plates 11 and 12, and a variable resistor VR1 having one end connected to the ground plate 12 and the other end connected to the ground.

FIG. 8 illustrates simulation results with respect to equivalent inductance of the transmission line CPW1 when the magnitude of the variable resistor VR1 is changed. It is understood that as the value R of the variable resistor VR1 increases, the inductance value of the transmission line CPW1 increases.

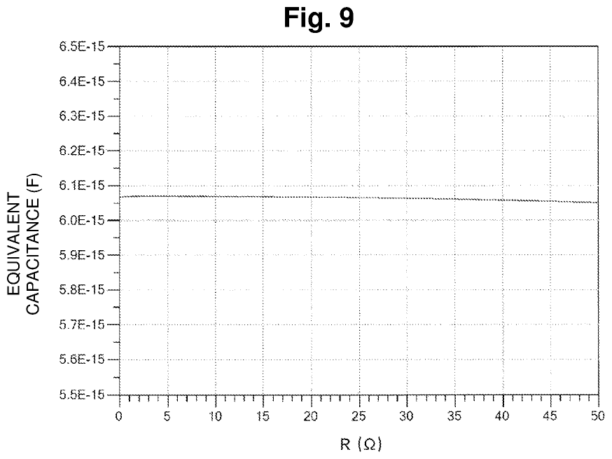

FIG. 9 illustrates simulation results with respect to equivalent capacitance of the transmission line CPW1 when the magnitude of the variable resistor VR1 is changed. In the present embodiment, as the value R of the variable resistor VR1 increases, the equivalent capacitance value of the transmission line CPW1 slightly decreases. The change in capacitance is small and negligible. Even if it is non-negligible, adjusting the variable capacitor Ctune1 so that the capacitance value thereof increases can compensate the reduction in capacitance.

As described above, according to the transmission line CPW1 of the present embodiment, the inductance can be adjusted without providing any switch for the signal line or distributing the signal.

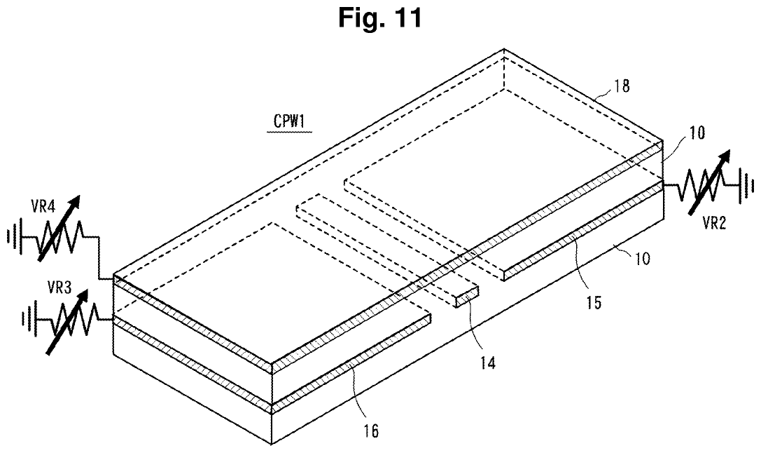

The configuration of the transmission line CPW1 is not limited to the configuration illustrated in FIG. 7, and therefor configurations illustrated in FIGS. 1 and 11 may be adopted.

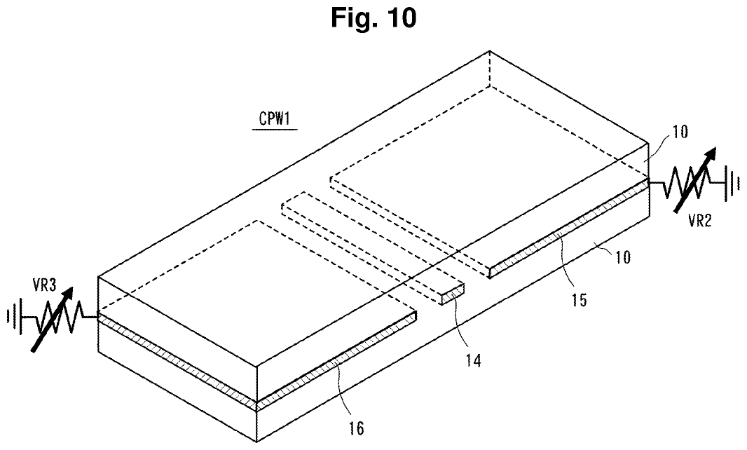

A transmission line CPW1 illustrated in FIG. 10 includes a planar dielectric 10, a signal line 14 composed of a belt-shaped conductor formed in the dielectric 10, ground plates 15 and 16 composed of planar conductors formed in the dielectric 10 so as to be parallel to the signal line 14 at positions where they face each other with the signal line 14 intervening therebetween, a variable resistor VR2 having one end connected to the ground plate 15 and the other end connected to the ground, and a variable resistor VR3 having one end connected to the ground plate 16 and the other end connected to the ground.

According to the configuration illustrated in FIG. 10, changing the magnitudes of the variable resistors VR2 and VR3 can adjust the inductance of the transmission line CPW1.

A transmission line CPW1 illustrated in FIG. 11 includes a dielectric 10, a signal line 14, ground plates 15 and 16, a ground plate 18 composed of a planar conductor formed on a front surface of the dielectric 10, variable resistors VR2 and VR3, and a variable resistor VR4 having one end connected to the ground plate 18 and the other end connected to the ground.

According to the configuration illustrated in FIG. 11, changing the magnitudes of the variable resistors VR2 to VR4 can adjust the inductance of the transmission line CPW1.

### Third Embodiment

Next, a third embodiment of the present invention will be described. The present embodiment describes a specific example of the variable resistor of the second embodiment.

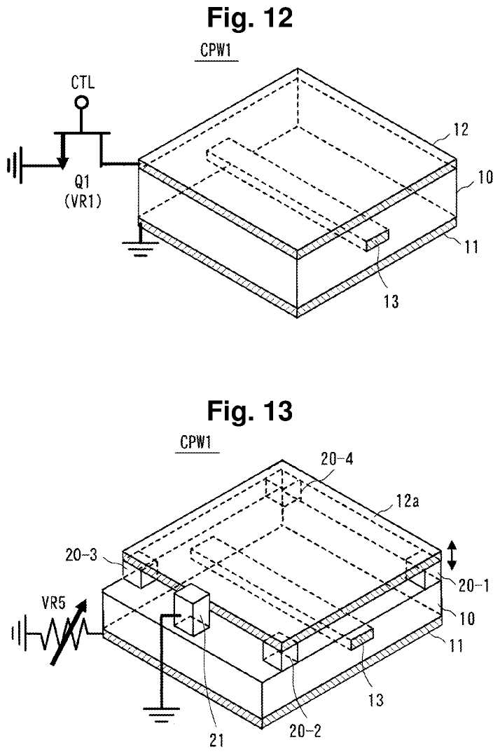

A method using a single MOS transistor Q1 as illustrated in FIG. 12 is the simplest method for realizing the variable resistor VR1 of the second embodiment. The MOS transistor Q1 has a gate terminal to which a voltage CTL for controlling the resistance value is input. The MOS transistor Q1 has a drain terminal connected to the ground plate 12. The MOS transistor Q1 has a source terminal connected to the ground.

Changing the gate voltage CTL can change the on-resistance of the MOS transistor Q1. Unlike a switch used in an ordinary signal line, it is desired that the MOS transistor Q1 used here is as larger as possible in size so that the on-resistance as small as possible can be realized.

Although the variable resistor VR1 is described in the above example, the variable resistors VR2 to VR4 of the second embodiment can also be realized by the MOS transistor in the same manner as the variable resistor VR1.

Further, although an NMOS transistor is used as the MOS transistor Q1 in the above example, it may be replaced by a PMOS transistor. In the case of using the PMOS transistor, the above description will be modified by replacing the drain terminal with the source terminal and also replacing the source terminal with the drain terminal.

### Fourth Embodiment

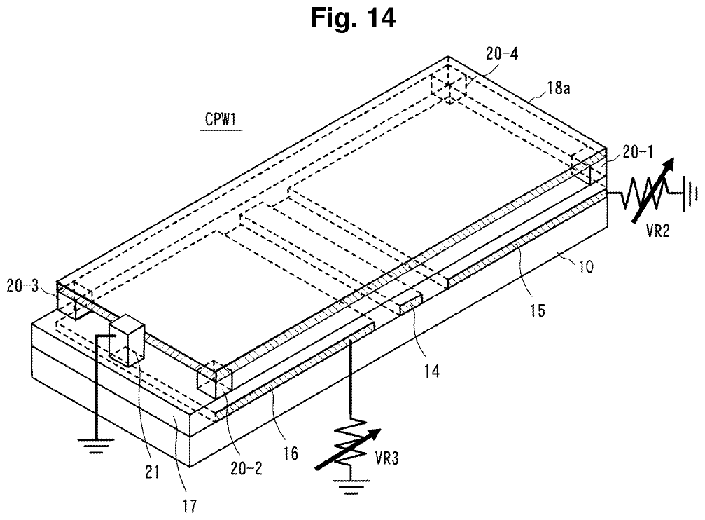

Next, a fourth embodiment of the present invention will be described. The present embodiment is an exemplary configuration in which the variable range of the inductance value of the transmission line of the second embodiment is further widened. FIG. 13 is a perspective diagram illustrating a configuration of the transmission line of this present embodiment, and configurations similar to those in FIG. 7 are denoted by the same reference numerals.

A transmission line CPW1 of the present embodiment includes a dielectric 10, a ground plate 11, a ground plate 12a composed of a planar conductor, a signal line 13, micro electro mechanical systems (MEMS) linear actuators 20-1 to 20-4 mounted on a front surface of the dielectric 10 and supporting the ground plate 12a so that the ground plate 12a is arranged above and separated from the dielectric 10, and configured in such a manner that the distance between the signal line 13 and the ground plate 12a is adjustable, a ground terminal 21 connected to the ground and composed of a conductor formed on the dielectric 10 so that a side face thereof is in contact with a side face of the ground plate 12a, and a variable resistor VR5 having one end connected to the ground plate 11 and the other end connected to the ground.

The MEMS linear actuators 20-1 to 20-4 can not only support the ground plate 12a but also move the ground plate 12a up and down according to a voltage supplied from the outside, thereby changing the distance between the signal line 13 and the ground plate 12a. The driving force for moving the ground plate 12a up and down is, for example, an electrostatic power.

The ground terminal 21 is formed on the dielectric 10 so that the side face thereof is in contact with the side face of the ground plate 12a. The height of an upper end of the ground terminal 21 is set to be higher than an upper face of the ground plate 12a in a highest position. Since the ground plate 12a is constantly in contact with the ground terminal 21 even when the position is changed by the MEMS linear actuators 20-1 to 20-4, the ground plate 12a is connected to the ground via the ground terminal 21.

As described above, in the present embodiment, the variable range of the inductance value of the transmission line CPW1 can be further widened by changing the distance between the signal line 13 and the ground plate 12a.

The configuration of the present embodiment may be applied to another configuration as illustrated in FIG. 14. A transmission line CPW1 illustrated in FIG. 14 is an example in which the configuration of the present embodiment is applied to the configuration illustrated in FIG. 11, and includes a dielectric 10, a signal line 14, ground plates 15 and 16, a ground plate 18a composed of a planar conductor, MEMS linear actuators 20-1 to 20-4 mounted on a front surface of the dielectric 10 and supporting the ground plate 18a so that the ground plate 18a is arranged above and separated from the dielectric 10, and configured in such a manner that the distance between the signal line 14 and the ground plate 18a is adjustable, a ground terminal 21 connected to the ground and composed of a conductor formed on the dielectric 10 so that a side face thereof is in contact with a side face of the ground plate 18a, and variable resistors VR2 and VR3.

Although the transmission line CPW1 is described in the second to fourth embodiments, the transmission line CPW2 is also applicable in realizing these embodiments in the same manner as the transmission line CPW1.

### Fifth Embodiment

Next, a fifth embodiment of the present invention will be described. In the first to fourth embodiments, the distributed amplifier is exemplarily described, but the present invention may be applied to any distributed circuit that requires adjustment of the impedance and the phase velocity. Distributed circuits to which embodiments of the present invention is applicable include distributed mixers and distributed oscillators.

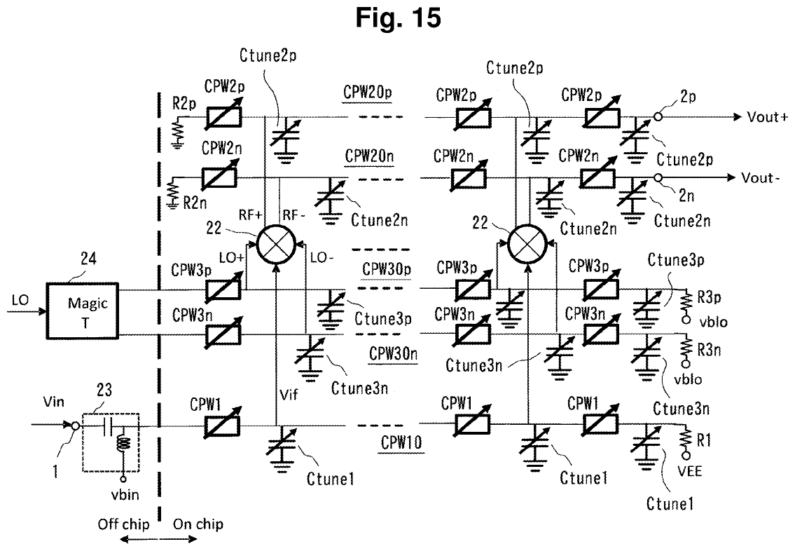

FIG. 15 illustrates an example in which an embodiment of the present invention is applied to a distributed mixer. The distributed mixer includes a transmission line CPW10 having an input end connected to a signal input terminal (IF terminal) 1, RF signal output transmission lines CPW20p and CPW20n having terminating ends connected to signal output terminals (RF terminal) 2p and 2n, LO signal input transmission lines CPW30p and CPW30n, an input terminating resistor R1 connecting a terminating end of the transmission line CPW10 to the ground, output terminating resistors R2p and R2n connecting input ends of the transmission lines CPW20p and CPW20n to the ground, terminating resistors R3p and R3n connecting terminating ends of the transmission lines CPW30p and CPW30n to a bias voltage vblo, arranged along the transmission lines CPW10, CPW20p, CPW20n, CPW30p, and CPW30n, a plurality of unit cells 22 each having an IF input terminal connected the transmission line CPW10 and LO input terminals connected to the transmission lines CPW30p and CPW30n, and RF output terminals connected to the transmission lines CPW20p and CPW20n, a bias tee 23 supplying a bias voltage to an input transistor in each unit cell 22, a branch waveguide 24 that splits the LO signal and inputs the split signals to input ends of the transmission lines CPW30p and CPW30n, a plurality of variable capacitors Ctune1 provided between the transmission line CPW10 and the ground, a plurality of variable capacitors Ctune2p and Ctune2n provided between the transmission lines CPW20p and CPW20n and the ground, and a plurality of variable capacitors Ctune3p and Ctune3n provided between the transmission lines CPW30p and CPW30n and the ground.

The transmission line CPW10 is configured to include a plurality of transmission lines CPW1 connected in series. The transmission line CPW20p is configured to include a plurality of transmission lines CPW2p connected in series. The transmission line CPW20n is configured to include a plurality of transmission line CPW2n connected in series. The transmission line CPW30p is configured to include a plurality of transmission line CPW3p connected in series. The transmission line CPW30n is configured to include a plurality of transmission line CPW3n connected in series.

In FIG. 15, Vin represents an input signal (IF signal) of the distributed mixer, and Vout+ represents an output signal (RF+ signal) on the positive phase side of the distributed mixer, and Vout− represents an output signal (RF-signal) on the negative phase side of the distributed mixer, LO+ represents an LO signal on the positive phase side, and LO− represents an LO signal on the negative phase side.

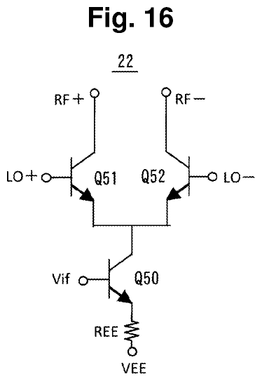

As illustrated in FIG. 16, each unit cell 22 includes an input transistor Q50 having a base terminal connected to the transmission line CPW1, output transistors Q51 and Q52 having base terminals connected to the transmission lines CPW3p and CPW3n, collector terminals connected to the transmission lines CPW2p and CPW2n, and emitter terminals connected to a collector terminal of the transistor Q50, and an emitter resistor REE having one end connected an emitter terminal of the input transistor Q50 and the other end connected to a power source voltage VEE.

The transmission lines CPW1, CPW2p, CPW2n, CPW3p, and CPW3n are configured so that their inductances are adjustable. That is, in the transmission line CPW1, the inductance is independently adjustable in a region between the signal input terminal 1 and a first-stage unit cell 22 (the leftmost unit cell 22 in FIG. 15), a region between the unit cells, and a region between the final-stage unit cell 22 (the rightmost unit cell 22 in FIG. 15) and the input terminating resistor R1.

In the transmission line CPW2p, the inductance is independently adjustable in a region between the output terminating resistor R2p and the first-stage unit cell 22, a region between the unit cells, and a region between the final-stage unit cell 22 and the signal output terminal 2p. In the transmission line CPW2n, the inductance is independently adjustable in a region between the output terminating resistor R2n and the first-stage unit cell 22, a region between the unit cells, and a region between the final-stage unit cell 22 and the signal output terminal 2n.

In the transmission line CPW3p, the inductance is independently adjustable in a region between the branch waveguide 24 and the first-stage unit cell 22, a region between the unit cells, and a region between the final-stage unit cell 22 and the terminating resistor R3p. In the transmission line CPW3n, the inductance is independently adjustable in a region between the branch waveguide 24 and the first-stage unit cell 22, a region between the unit cells, and a region between the final-stage unit cell 22 and the terminating resistor R3n. The configurations described in the second to fourth embodiments can be used as the transmission lines CPW1, CPW2p, CPW2n, CPW3p, and CPW3n.

The variable capacitor Ctune1 is provided at a position between the transmission lines CPW1, and is also provided at a position between the transmission line CPW1 and the input terminating resistor R1. The variable capacitor Ctune2p is provided at a position between the transmission lines CPW2p, and is also provided at a position between the transmission line CPW2p and the signal output terminal 2p. The variable capacitor Ctune2n is provided at a position between the transmission lines CPW2n, and is also provided at a position between the transmission line CPW2n and the signal output terminal 2n. The variable capacitor Ctune3p is provided at a position between the transmission lines CPW3p, and is also provided at a position between the transmission line CPW3p and the terminating resistor R3p. The variable capacitor Ctune3n is provided at a position between the transmission lines CPW3n, and is also provided at a position between the transmission line CPW3n and the terminating resistor R3n.

With the above-described configuration, the present embodiment can independently adjust the input/output impedances and the phase velocities, and can realize a distributed mixer in which the input/output impedances and the phase velocities are adjustable after manufacturing, without deteriorating both the reflection characteristics and the band characteristics.

### INDUSTRIAL APPLICABILITY

Embodiments of the present invention can be applied to distributed circuits.
1 . . . signal input terminal
2 . . . signal output terminal
3, 22 . . . unit cell
10, 20 . . . dielectric
11, 12, 15, 16, 18 . . . ground plate
13, 14 . . . signal line
20-1 to 20-4 . . . MEMS linear actuator
21 . . . ground terminal
23 . . . bias tee
24 . . . branch waveguide
CPW 1, CPW2, CPW2p, CPW2n, CPW3p, CPW3n, CPW10, CPW20, CPW20p, CPW20n, CPW30p, CPW30n . . . transmission line
Ctune1, Ctune2, Ctune2p, Ctune2n, Ctune3p, Ctune3n . . . variable capacitor
R1, R2, R2p, R2n, R3p, R3n . . . resistor
VR1 to VR5 . . . variable resistor
Q1 . . . MOS transistor

1-8. (canceled)

9. A distributed circuit comprising:
a transmission line configured so as to transmit a signal; and
a variable capacitor having one end connected to the transmission line and the other end connected to the ground, and configured so that the capacitance is adjustable, wherein
the transmission line is configured in such a manner that the inductance is adjustable.

10. The distributed circuit according to claim 9, wherein the transmission line includes
a first ground plate composed of a conductor on a back surface of a dielectric and connected to the ground,
a second ground plate composed of a conductor on a front surface of the dielectric,
a signal line composed of a conductor formed in the dielectric so as to be parallel to the first and second ground plates, and
a variable resistor having one end connected to the second ground plate and the other end connected to the ground.

11. The distributed circuit according to claim 10, wherein
the variable resistor includes a MOS transistor having
a gate terminal to which a voltage for controlling a resistance value is input,
a first terminal, which is one of a drain terminal and a source terminal, is connected to the second ground plate, and
a second terminal, which is the other of the drain terminal and the source terminal, is connected to the ground.

12. The distributed circuit according to claim 9, wherein the transmission line includes
a signal line composed of a conductor formed in a dielectric,
a first ground plate and a second ground plate composed of conductors formed in the dielectric so as to be parallel to the signal line at positions where they face each other with the signal line intervening therebetween,
a first variable resistor having one end connected to the first ground plate and the other end connected to the ground, and
a second variable resistor having one end connected to the second ground plate and the other end connected to the ground.

13. The distributed circuit according to claim 9, wherein the transmission line includes
a signal line composed of a conductor formed in a dielectric,
a first ground plate and a second ground plate composed of conductors formed in the dielectric so as to be parallel to the signal line at positions where they face each other with the signal line intervening therebetween,
a third ground plate composed of a conductor on a front surface of the dielectric, and
a first variable resistor having one end connected to the first ground plate and the other end connected to the ground.

14. The distributed circuit according to claim 13, wherein the transmission line further includes
a second variable resistor having one end connected to the second ground plate and the other end connected to the ground, and
a second variable resistor having one end connected to the third ground plate and the other end connected to the ground.

15. The distributed circuit according to claim 9, wherein the transmission line includes
a first ground plate composed of a conductor on a back surface of a dielectric,
a signal line composed of a conductor formed in the dielectric so as to be parallel to the first ground plate,
a second ground plate composed of a conductor,
an MEMS actuator mounted on a front surface of the dielectric and supporting the second ground plate so that the second ground plate is arranged above and separated from the dielectric, and configured in such a manner that the distance between the signal line and the second ground plate is adjustable,
a variable resistor having one end connected to the first ground plate and the other end connected to the ground, and
a ground terminal connected to the ground and composed of a conductor on the dielectric so as to be in contact with a side face of the second ground plate.

16. The distributed circuit according to claim 9, wherein the transmission line includes
a signal line composed of a conductor formed in a dielectric,
a first ground plate and a second ground plate composed of conductors formed in the dielectric so as to be parallel to the signal line at positions where they face each other with the signal line intervening therebetween,
a third ground plate composed of a conductor,
an MEMS actuator mounted on a front surface of the dielectric and supporting the third ground plate so that the third ground plate is arranged above and separated from the dielectric, and configured in such a manner that the distance between the signal line and the third ground plate is adjustable,
a first variable resistor having one end connected to the first ground plate and the other end connected to the ground,
a second variable resistor having one end connected to the second ground plate and the other end connected to the ground, and
a ground terminal connected to the ground and composed of a conductor on the dielectric so as to be in contact with a side face of the third ground plate.

17. The distributed circuit according to claim 9, wherein the distributed circuit further comprises:
a first terminating resistor connected to a terminating end of the transmission line;
a second terminating resistor connected to an input end of the transmission line; and
a plurality of unit cells arranged along the transmission line,
wherein the transmission line includes
a first transmission line configured to have an input end to which an input signal is input, and
a second transmission line configured to have an output end from which an output signal is output,
the variable capacitor includes
a first variable capacitor connected to the first transmission line and connected to the ground at the other end, and
a second variable capacitor connected to the second transmission line and connected to the ground at the other end,
the first terminating resistor is connected to a terminating end of the first transmission line,
the second terminating resistor is connected to an input end of the second transmission line,
the unit cells are arranged along the first and second transmission lines, and having an input terminal connected to the first transmission line and an output terminal connected to the second transmission line,
the first transmission line includes a region between a signal input terminal and a first-stage unit cell, a region between the unit cells, a region between a final-stage unit cell and the first terminating resistor, which are connected in series, and is configured so that the inductance is independently adjustable in each region,
the second transmission line includes a region between the second terminating resistor and a first-stage unit cell, a region between the unit cells, and a region between a final-stage unit cell and a signal output terminal, which are connected in series, and is configured so that the inductance is independently adjustable in each region,
the first variable capacitor is provided at a position between respective regions of the first transmission line, and is also provided at a position between the first transmission line and the first terminating resistor, and
the second variable capacitor is provided at a position between respective regions of the second transmission line, and is provided at a position between the second transmission line and the signal output terminal.

18. A distributed circuit comprising:
a transmission line configured so as to transmit a signal; and
a variable capacitor having one end connected to the transmission line and the other end connected to the ground, and configured so that the capacitance is adjustable, wherein
the transmission line comprises
a first ground plate composed of a conductor on a back surface of a dielectric and connected to the ground,
a second ground plate composed of a conductor over a front surface of the dielectric,
a signal line composed of a conductor in the dielectric so as to be parallel to the first and second ground plates, and
a variable resistor having one end connected to the first ground plate and the other end connected to the ground.

19. The distributed circuit according to claim 18, wherein
the variable resistor includes a MOS transistor having
a gate terminal to which a voltage for controlling a resistance value is input,
a first terminal, which is one of a drain terminal and a source terminal, is connected to the first ground plate, and
a second terminal, which is the other of the drain terminal and the source terminal, is connected to the ground.

20. The distributed circuit of claim 18, wherein the transmission line further comprises
an MEMS actuator on a front surface of the dielectric and supporting the second ground plate so that the second ground plate is arranged above and separated from the dielectric, and configured in such a manner that the distance between the signal line and the second ground plate is adjustable.
